(19) United States
(12) Patent Application Publication
(10) Pub. No.: US 2007/0277161 A1
(43) Pub. Date: Nov. 29, 2007

(54) System and Method for Programmable Logic Acceleration of Data Processing Applications and Compiler Therefore

(75) Inventors: Martin C. Herbordt, Wayland, MA (US); Thomas Van Court, Charlestown, MA (US)

Correspondence Address: WEINGARTEN, SCHURGIN, GAGNEBIN & LEBOVICI LLP, TEN POST OFFICE SQUARE, BOSTON, MA, 02109, US

(73) Assignee: TRUSTEES OF BOSTON UNIVERSITY, Boston, MA (US)

(21) Appl. No.: 10/591,680

(22) PCT Filed: Mar. 4, 2005
(86) PCT No.: PCT/US05/07278

§ 371 Date: Jul. 24, 2007

Related U.S. Application Data
(60) Provisional application No. 60/549,946, filed on Mar. 4, 2004.

(51) Int. Cl. G06F 9/45; G06F 17/50; H03K 19/00; G06F 9/44

(52) U.S. Cl. 717/140

(57) ABSTRACT

An accelerated processor for use in massive data manipulations specific to an application. A workstation has a general purpose processor and a coprocessor connection to which an application specific coprocessor system is connected. The coprocessor system has programming code which is assembled as instructions for the specific application in combination with accelerator environment specific requirements, independently provided but designed to allow non design experts to input application specific code.

### CROSS REFERENCE TO RELATED APPLICATIONS

This application claims the priority of U.S. Provisional Application No. 60/549,946 filed Mar. 4, 2004 and entitled SYSTEM AND METHOD FOR PROGRAMMABLE-LOGIC ACCELERATION OF BIOIONFORMATICS AND COMPUTATIONAL BIOLOGY APPLICATIONS

### STATEMENT REGARDING FEDERALLY SPONSORED RESEARCH OR DEVELOPMENT

N/A

### FIELD OF THE INVENTION

This invention relates generally to programmable electronic devices and more particularly to a method and apparatus for utilizing programmable electronic devices in bioinformatics and computational biology (BCB) applications.

### BACKGROUND OF THE INVENTION

Biologists have devised methods for accumulating large amounts of genetic DNA sequence information. Because considerable information may be found by comparing the DNA sequences between different genes and organisms, major efforts are underway to sequence the DNA from many different human individuals, and many different species. Due to the high speed of modern sequencing technology, biologists accumulate data at a rate which greatly exceeds known techniques for analyzing the data. The biological sequences, such as DNA, RNA or protein sequences are stored as linear arrays of characters where each character corresponds to a base element or residue of the particular sequence. Such linear character arrays are typically referred to as strings.

As an example of usage needs, microarray data, at 100,000 data values per experiment or more is typical in screening of drug candidates, with other applications possible in the future.

As is also known in the art, the term “bioinformatics” refers to the use of computer processors and computer related technology to automate the process of interpreting the above-mentioned large amounts of data. To efficiently process the large amounts of biological data, algorithms referred to as bioinformatics algorithms have been developed.

Bioinformatics algorithms have been developed to compare full or partial sequences depending upon the particular biological problem being addressed. Often a choice of several algorithms exists for solving a given problem. The algorithms can be implemented using general purpose processors, specially designed custom integrated circuits (ICs) or programmable devices.

General-purpose computer processors are designed for flexibility and thus are useful for a wide variety of applications. One problem with using general-purpose computer processors, however, is the speed with which they can process the large amounts of data.

Specially designed custom ICs can be optimized to rapidly implement functions required in a specific bio-informatics algorithm or a specific biological problem. One problem with this approach, however is that custom ICs are relatively expensive and require a relatively long lead time to fabricate. Furthermore, it is often desirable to try more than one algorithm to solve the same problem or it may be desirable to try or variants of one algorithm on the same problem. Thus, the custom IC approach can be quite costly and time consuming and lacks needed flexibility.

Programmable devices such as field programmable gate array (FPGA) circuits can be used to facilitate high-speed processing of fixed algorithms. FPGA circuits are composed of a plurality of simple logical elements, and programmable means to dynamically rewire the connections between the various logical elements to perform different specialized logical tasks. Often this is accomplished by fuse-antifuse circuit elements (or gates) that connect the various FPGA logical circuits. These fuse-antifuse elements can be reconfigured by applying appropriate electrical energy to the FPGA external connectors, causing the internal FPGA logical elements to be connected in the appropriate manner. More modern FPGAs use reprogrammable memory circuits for controlling the FPGA connections, allowing redesign of the FPGA functionality.

An alternate way to produce custom integrated circuit chips suitable for the implementation of custom algorithms is by more standard chip production techniques, in which a fixed logical circuit is designed into the very production masks used to produce the chip. Because such chips are designed from the beginning to implement a particular algorithm, they often can be run at a higher logic density, or faster speed, than more general purpose FPGA chips, which by design contain many logical gates that will later prove to be redundant to any particular application.

Several exemplary prior art are systems are commercially available. For example, one system based upon based upon custom VLSI sequence analysis chips is the GeneMatcher2™ genetic analysis system manufactured by Paracel Corporation (1055 East Colorado Boulevard, Fifth Floor Pasadena, Calif. 91106-2341). Another system, based upon custom FPGA chip technology, is the DeCypher™ genetic analysis system manufactured by TimeLogic Corporation (1914 Palomar Oaks Way, Suite 150, Carlsbad Calif. 92008). Still another system based upon FPGA chip technology is the SysGen system manufactured by XiLinx (2100 Logic Drive, San Jose, Calif. 95124-3400).

None of these currently provide a system and technique which can rapidly implement bioinformatics algorithms and which allows a user to implement a number of different algorithms in a relatively short period of time. It would be further desirable to provide a relatively inexpensive processing platform (e.g. a personal computer) which can rapidly perform computations for BCB applications. It would also be desirable to provide a system which provides the function of convention FPGA-based turn-key products provide, but at lower cost and with the capability to extend the utility to many, if not most, BCB computations.

### SUMMARY OF THE INVENTION

The present invention provides a system that enables BCB researchers to create FPGA configurations (circuit designs) that yield speed-ups of a factor of 1000 and greater for a wide variety of BCB and other high massive data processing applications. The system starts with a problem specification for a particular application from a user and performs two transformations: (1) problem specification to circuit specification; and (2) circuit specification to circuit implementation. The users can be bioinformatics practitioners or computational support staff in bioinformatics groups. It should be appreciated that the circuit specification to circuit implementation transformation is normally the realm of a circuit designer. Thus, the system of the present invention allows a user without circuit design expertise (e.g. a bioinformatics practitioner or computational support person in a bioinformatics group) to generate circuits for use in a bioinformatics application.

According to the present invention, an FPGA-based computational coprocessor includes a compiler, a set of domain specific policies and rules for user defined custom applications, a set of hardware contexts and application independent but FPGA hardware specific code. These are preset typically with the aid of a design specialist so that an application specialist can then specify the FPGA wiring instructions in a form friendly to that user. The compiler with this user information performs flow analysis/precision management operations, maps hardware resources and determines the amount of parallelism which can be included in a circuit and performs resource balancing and provides code for an FPGA circuit via a conventional processor.

### BRIEF DESCRIPTION OF THE DRAWINGS

The foregoing features of this invention, as well as the invention itself, may be more fully understood from the following description of the drawings in which:

FIG. 1 is a block diagram of a system for providing code to program an FPGA circuit;

FIG. 1A is a block diagram of a compiler which performs at least one of flow analysis/precision management operations, mapping of hardware resources, determining the amount of parallelism which can be included in a circuit and resource balancing;

FIG. 2 is a block diagram of a system which performs BCB computations using a hardware accelerator provided from an FPGA circuit.

### DETAILED DESCRIPTION OF THE INVENTION

The present invention relates to the use of field programmable gate arrays (FPGAs) in BCB applications. The FPGA is an integrated circuit that contains many (64 to over 10,000) identical logic cells that can be viewed as standard components. Each logic cell can independently take on any one of a limited set of personalities. The individual cells are interconnected by a matrix of wires and programmable switches. A user's design is implemented by specifying the simple logic function for each cell and selectively closing the switches in the interconnect matrix. The array of logic cells and interconnect form a fabric of basic building blocks for logic circuits. Complex designs are created by combining these basic blocks to create the desired circuit.

The logic cell architecture varies between different device families. Generally speaking, each logic cell combines a few binary inputs (typically between 3 and 10) to one or two outputs according to a Boolean logic function specified in the user program. In most families, the user also has the option of registering the combinatorial output of the cell, so that clocked logic can be easily implemented. The cell's combinatorial logic may be physically implemented as a small look-up table memory (LUT) or as a set of multiplexers and gates. LUT devices tend to be a bit more flexible and provide more inputs per cell than multiplexer cells at the expense of propagation delay.

The FPGA's function is defined by a program written by someone other than the device manufacturer. Depending on the particular device, the program is either ‘burned’ in permanently or semi-permanently as part of a board assembly process, or is loaded from an external memory each time the device is powered up. This user programmability gives the user access to complex integrated designs without the high engineering costs associated with application specific integrated circuits. It is the function of the compiler in this invention to create the code that the FPGA will use for an application specific use.

Defining the many switch connections and cell logic is handled by special software. The software translates a user's schematic diagrams or textual hardware description language code then places and routes the translated design. The software packages have hooks to allow the user to influence implementation, placement and routing to obtain better performance and utilization of the device. Libraries of more complex function macros (e.g. adders) further simplify the design process by providing common circuits that are already optimized for speed or area.

As used in the invention, acceleration hardware could be any hardware product that contains one or more user-programmable FPGAs and an interface to a host processor. Typical products include Wildstar-II Pro™ systems from Annapolis Micro Systems, Inc. or the PROCSuperStar™ from Gidel Ltd. Any one family of acceleration hardware products typically offers some range of configuration options. Within the Wildstar II Pro product family, there are choices of one or two FPGAs, choices between Xilinx XC2VP70 or XC2VP100 models of FPGA, and choices of on-board memory capacity. Individual Gidel boards are available in only one configuration, but one to seven of them can configured together into hardware accelerators of different capacities, and memory capacity can be increased with additional memory boards.

In one aspect of the present invention, the system of the present invention relates to a method and apparatus for providing an FPGA circuit for use in a bioinformatics application. The system include a series of templates or software components which can be customized by a user to implement a particular function in an FPGA circuit which is adapted for use in a bioinformatics application. The system automatically analyzes a variety of factors to determine the number of functional blocks which can be used on the FPGA and the system also automatically determines the degree of parallelism and the width of certain data which can be implemented in the FPGA such that the FPGA can perform rapid bioinformatics computations.

In another aspect of the present invention, a system which includes an FPGA co-processor circuit adapted for processing BCB applications, is described.

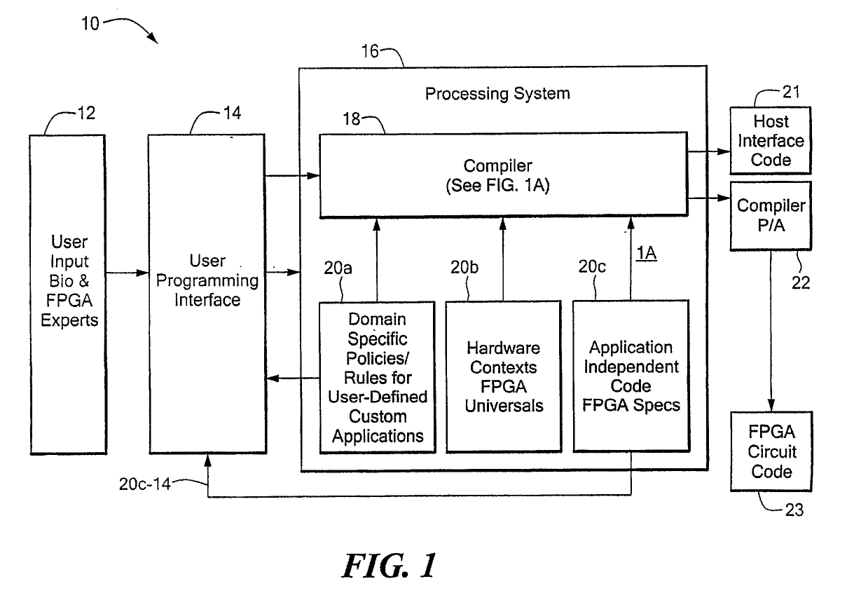

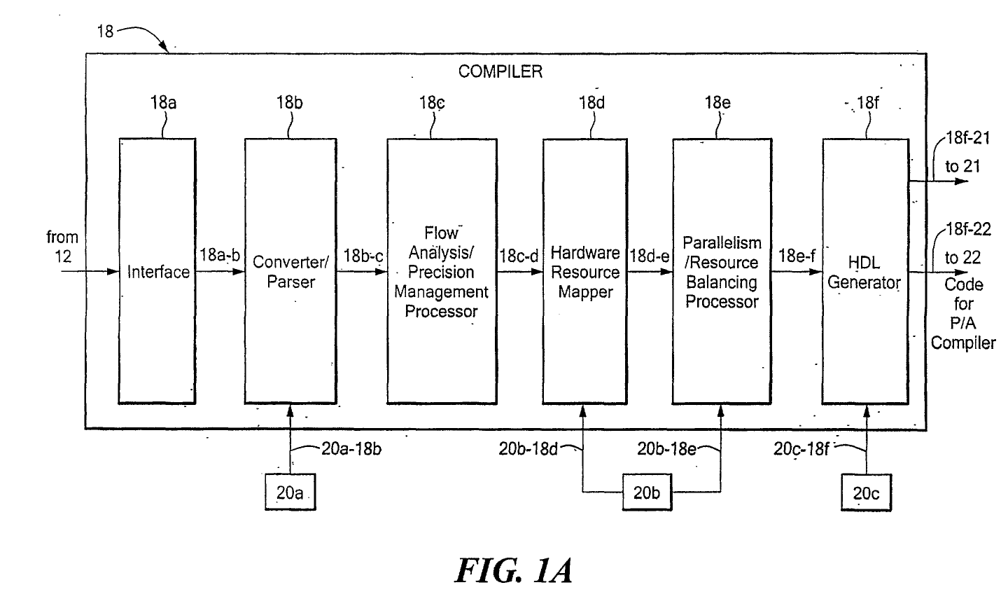

Referring now to FIG. 1, a system 10 for generating FPGA circuit code includes a user programming interface 14 which accepts user input 12. User input represents the choices made by an application specialist, and generally covers two bodies of data: the test data and the rules according to which it is tested. In most cases, the rules will be held constant across some number of tests, and the test data will be varied for each specific test. The rules are encoded in the logic of the FPGA accelerator, and the test data are processed by the accelerator.

In a drug screening application, for example, the molecules (protein or other biomolecules and the drug candidates) are the test data and the laws of chemistry are the rules by which each set of test data is evaluated. Although the real-world laws of chemistry are fixed, researchers pick different mathematical approximations to the real-world laws. These approximations may include some combination of the following, or possibly other phenomena:
Mechanical interference between atoms,
Electrostatic charge,
Atomic contact potential,
Shape and orientation of the molecule's surface.

The application specialist encodes this information as a mathematical function, using a notation with familiar similarity to standard programming languages.

The user programming interface 14 accepts domain-specific policy information 20c-14. It also accepts the application specialist's input 12-14, using some combination of textual input and graphical interface based on the domain-specific policy. The user programming interface 14 validates the application specialist's input with respect to the constraints set in the domain-specific policy, and generates a partially processed output 14-18a. The interface 14 provides the user input to a processing system 16. Processing system 16 also includes a compiler 18 the details of which will be discussed below in conjunction with FIG. 1A.

The compiler 18 accesses preprogrammed instructions in memories or data sources 20a through 20c created by an FPGA design expert in conjunction with knowledge provided by an expert in an application area that the final FPGA is to be used in. That enables compiler 18 to respond to user instructions that the user, an expert in an application but not in FPGA design, can provide.

For this purpose design specific information for the general nature of the application is provided as domain specific polices in a data or code source 20a. The application “domain” is a bounded family of computations. Current examples of domains in the bioinformatics field include correlation-based molecule interactions and dynamic programming for approximate string comparison. The domain represents an intermediate level of specificity in a calculation. It lays out the general plan of the calculation, including the computing elements that can be replicated to increase the calculation's parallelism.

The domain-specific policy is represented as a set of data, and possibly some executable code (a “plug-in”) to be invoked by the compiler when invoked to produce FPGA coding for a specific application. This consists of two broad kinds of information. One is the abstract specification of the functions and data values to be provided as user input values, 12. The other is a specification in VHDL or other hardware description language (HDL) of the hardware components that comprise the hardware accelerator, annotated with markers indicating where the application-specific logic is to be inserted into the components that are generic across the entire application domain.

The abstract specification gives a partial definition of the information allowing tailoring of the accelerator to an application's specifics by a non design expert. For example, a correlation-based molecule interaction application specifies the following:
A data type representing one unit of molecule volume and a padding constant representing an empty volume element,
A data type representing a score for ranking molecule interactions and constants used to help find the best among all scores,
A function for comparing one unit volume of interaction between two molecules,
A function for adding two scores (which are not necessarily integer values), and
A function for determining which is the better of two scores.

The abstract specification states only that these symbols must be defined, but does not give concrete definitions for any of them. The application specialist defines any one unique application by providing implementations for these symbols. For example, the unit of molecule volume may be as simple as a bit indicating whether that unit volume is or is not interior to the molecule. In more complex applications, the unit volume includes electrostatic information and complex force field descriptions that approximate quantum mechanical models of chemistry.

Annotated HDL code in the domain-specific policy data is never seen by the application specialist. This is the code that represents the structural outline of the computation common across all members of that application domain. Annotation for the HDL includes functions that express scaling relations describing how logic resource utilization increases with numbers of processing elements. This is described more completely, in the description of the hardware resource mapper 18d.

Preset programming content which is applicable to all applications in all hardware contexts is provided in a data or code source 20b in which is information for FPGA operation applicable regardless of the FPGA chip family being used or the type of board carrying the FPGA chip. The hardware context information embodies the differences between configurations of a given family of acceleration hardware. It embodies the information that differs for each different FPGA in that family, such as numbers of logic gates, amount of available RAM, and numbers of hardware multipliers. Where hardware resources can be used in different ways, this logic represents the tradeoffs (e.g. RAMs being used as lookup tables in place of combinational logic or arithmetic hardware).

Domain-specific policy and hardware context information overlap in some places. Different models of FPGA and different accelerator boards offer different system interfaces and off-chip resources. In those cases, the differences between accelerator boards may be too large for convenient representation in parametric form.

FPGA specific hardware definitions in data or code source is embedded in application code 20c which information is independent of any application (and thus can be used for any application) but which is dependent upon the particular type of hardware used in the system. That is, for any combination of FPGA chip and circuit board which will be used, there will be corresponding information in storage 20c which matches the specific FPGA hardware embodiment. This data set is reused by all application domains, but differs according to the family of acceleration hardware in use. This includes HDL code for system interfaces and for access to off-chip resources on the accelerator board. Depending on the specific accelerator board, it may also implement communication protocols between multiple FPGAs on one board, or perform other interfacing tasks needed by a specific hardware configuration.

Thus, the processing system includes application specific content, application independent-hardware independent content and application independent-hardware specific content. It should be appreciated that some of the content in each of boxes 20a-20c may be represented as data and some as executable code and that the particular manner in which the content represented (e.g. as data or code) is selected for ease of use in the system.

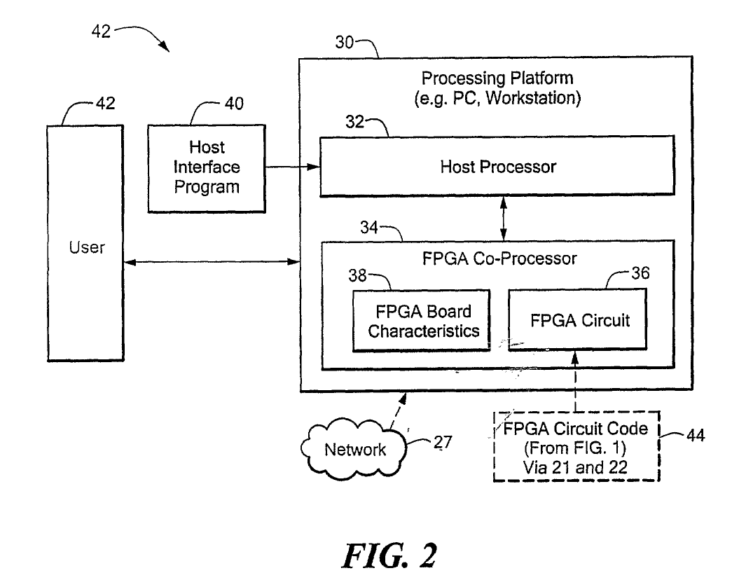

The compiler 18 provides two outputs: (1) host interface code and (2) high level language (HLL/HDL) code which can be fed to a conventional compiler 22 which provides appropriate FPGA circuit code 23 which can be loaded onto an FPGA (e.g. FPGA circuit 26b in FIG. 2) as in known in the art. It should be appreciated that compiler 22 includes conventional synthesis tools and others tools as is generally known. The compiler is discussed below with reference to steps 18a-f which may be software or hardware or combinations thereof.

Referring now to FIG. 1A, the compiler 18 includes an interface 18a (which may be provided for example as a GUI/textual interface) which receives in an interactive input manner user input values such as text and block diagram presentations of the bioinformatics problem to be solved from user 12 in FIG. 1 and provides the values to a parser/converter 18b. Interface 18a accepts data produced by the User Programming Interface 14, however it is represented. A typical implementation would accept one or more files saved in a conventional host file system. Similar units, represented by connection lines (20b-18d being one example) throughout the figures also control access to the stored forms of Hardware Contexts 20b-18d or 20b-18e, and stored forms of Application Independent Code 20c-18f.

The user can be a bioinformatics practitioner or computational support staff in bioinformatics groups or a combination of the two. It should be appreciated that a circuit specification to circuit implementation transformation is normally the realm of a circuit designer however, in this system, once the user inputs certain information, the system will automatically generate a circuit specification using the compiler 18 and the preset information from units 20a-20c. Thus, the system of the present invention allows a bioinformatics user without circuit design expertise to generate circuits for use in a bioinformatics application.

The parser/converter 18b receives data which represents the system design, as specified by the user input 12 via an interface such as user programming interface 14. The converter/parser 18b accepts the stored data format (for example, text data in an XML-based format) as input. It also accepts a description of the Domain Specific elements 20a-18b into which the user's application-specific logic is bound. It generates internal representations in unspecified form as output 18b-c. These internal representations include conventional data flow graph information and any other content needed for later analysis steps. The data received includes the text and general block diagrams which have been entered and converts this information to an internal representation reflecting the operational characteristics of an FPGA so that different mathematical operations can be identified. This identifies the logic operations in terms of addition, multiplication etc. needed to address the bioinformatics problem and enables the process of connecting different blocks to each other within the FPGA and begins to build a model based upon what the user has inputted. Thus in summary, this phase accepts as input the application-specific design information 18a-b and the domain-specific policy information 20b-18b. It parses the XML-formatted inputs into internal data structures. It then confirms that the user input has proper logical structure and meets the domain-specific policy specification.

The parser/converter provides these basic building block specifications to a flow analysis precision management processor 18c. It should be appreciated that parser/converter performs technology independent transformations.

A flow analysis precision management processor 18c receives the output specifications of the converter/parser 18b and determines circuit characteristics such as bit width allocation, bit precision, etc. required by the FPGA for the bioinformatics problem to be solved. This results in a determination of the number of bits which will be used at every part in the calculation performed in general terms and independent of any particular FPGA. The flow analysis/precision management unit produces output 18c-d which contain additional information deduced from the content of the input representation. These additions specify the number of bits needed at each step in the calculation to meet the user's goals for precision, for acceptable probability of numerical overflow or underflow, etc.

Data flow analysis is the process of tracing data values from their origin as inputs, through some set of arithmetic and logic operations performed on them, to their eventual use as outputs from the system. Precision management examines a calculation with respect to erroneous outputs due to arithmetic overflow and due to rounding errors. The outcome of precision management analysis is that each intermediate step in the calculation is allocated the minimal number of bits necessary for producing a final result that fulfills domain-specific objectives.

The techniques used in precision management depend on the problem being solved. For example, grid-based molecule interactions do not need to handle the ‘worst case’ result, in which every unit of volume contributes the most extreme value to the scores. First, that case does not represent a physically meaningful set of molecule interactions. Real-world data sets always produce extreme scores at only a subset of the unit volumes. Second, positive and negative scoring results tend towards arithmetic cancellation. There is a very low probability of partial scores summing in one direction, without cancellation. The number of bits in the calculation needs to cover only range of scores that occur with non-negligible probability. Third, the most extreme scores tend not to be meaningful. If, after part of the calculation, a molecule interaction has already been found to be infeasible, it is not necessary to compute a larger penalty value—the interaction remains infeasible. There is no need to total more digits of infeasibility.

The flow analysis precision management processor provides the data generated therein, 18c-d, to a hardware resource mapper 18d. The hardware resource mapper has two sets of input information, the application-specific data 18c-d and the description of the set of logic resources on a specific model of FPGA accelerator with a specific model of FPGA integrated circuit, 20b-18d. This step's/circuit's responsibility is to estimate the amount of logic needed for each component in the resulting logic design and to determine the number of component instances that can be implemented using the logic resources available on that FPGA and accelerator. This also generates timing estimates, including the numbers of clock cycles and minimum allowable clock period for the logic components. The hardware resource mapper examines the different arithmetic operations specified for the application and identifies appropriate hardware to carry out the operation. For example, if the hardware resource mapper identified a small multiply (e.g. a 2 bit times 2 bit multiply) and a large multiply (e.g. a 12 bit times 14 bit multiply) then the mapper may decide that the large multiple can use special hardware if it is available and the small multiply will not benefit from the special hardware. Thus, the mapper begins taking the hardware resources from unit 20b and begins to allocate these resources to perform the abstract logic functions identified to it.

More particularly, the hardware resource mapper accepts two sets of input. First, the hardware context information 20b-18d describes the quantities of hardware resources available within the chosen FPGA chip. Second, the results of flow analysis and precision management give information needed for estimating the logic resources required by each part of the application-specific logic. Together, these data control the number of repeatable processing elements that will be instantiated in the application-specific accelerator.

All of the application domains under consideration consist of a repetitive array of processing elements with a regular communication pattern. The processing element is defined by the combination of user input and annotated HDL code from the domain-specific policy information. Automated analysis of the user input and annotations in the HDL code combine to yield resource estimates for each component.

Hardware context information provides the available quantities of each kind of logic resource. Those data, plus component resource estimates, are processed by functions provided as part of the HDL annotation. The result specifies the actual number of repeated processing elements to instantiate.

The domain-specific policy provides functions that decide how to scale the application-specific accelerator to make maximum use of available FPGA resources. This must be provided by the domain-specific policy because accelerators for different domains follow such different scaling laws. For example, in the grid-based molecule interaction domain, the allowed size of one molecule grows roughly as the cube root of available logic resources, but the allowed size of the other molecule is limited by the cube root of RAM resources, with terms that depend on the size of the first molecule. In the string-matching problem, allowed problem size grows linearly with the amount of logic available when only scores are required. When exact alignments are required, however, the application-specific accelerator's size may be limited by the square root of the amount of RAM on the FPGA. Depending on the details of the application and on the quantities of each resource on the FPGA, either logic or RAM could become the resource that limits the size of the application-specific accelerator.

Accurate synthesis estimation, the process of estimating the actual logic utilization for a given HDL function, is an open problem and is not solved here. Instead, these estimates are rough and conservative. The compiler features involved in synthesis estimation are well contained, however. That makes it easy to improve the resource estimates and FPGA resource utilization in the future, as better estimation techniques become available.

When there are repetitive processing elements in an application-specific processor, existing tools require the circuit specification to state the number of repetitions. The mapper in the current system differs. It accepts as input domain-specific policy information, estimates of the amount of logic needed for each processing element, and hardware context information that states what amounts of each logic resource exist on a given FPGA chip. The outcome is a design with largest possible number of processing elements that the specific FPGA can support. If only the FPGA description is changed, but no other user input or domain-specific policy, more processing elements can be synthesized.

At this point the compiler 18 has generated a “thumbnail sketch” of all of the hardware resources which will be required.

It should be appreciated that the mapper has some technology dependencies in using information supplied in unit 20b and at the output of the hardware mapper it is known (to at least a first approximation) the hardware resources that each user-specified operation will require as well as a thumbnail estimate for timing requirements for each of those units.

The hardware resource mapper 18d provides the information generated therein to a parallelism/resource balancing processor 18e. Processor 18e also has technology dependencies as inputs from units 20b. Parallelism/resource balancing processor 18e determines the number of parallel processing units of a particular type which will be used in a finally programmed FPGA circuit as well are the types of distribution and collection circuits which will be used to achieve rate balancing. It should be understood that time is considered a resource within the context of this processing. When applicable, step 18e combines the timing and resource estimates for each consecutive component of a calculation so as to utilize each component as high a percentage of the time as possible. This step may not be wholly distinct from 18d, since parallelism, synchronization logic, hardware resource allocation, and timing behavior are often mutually dependent quantities.

The goal of parallelism/resource balancing, or ‘rate balancing’, is to achieve high utilization of all processing elements in a computation pipeline, even when processing element execute at different rates. The resource balancing stage is unique, in that it analyzes the processing speed at each step, and allocates parallel hardware in proportion to speed requirements.

As an example of how balancing can be used, suppose, in case one, three serial processing elements handle data at 1, 4, and 2 requests per unit time, respectively. The system as a whole runs at the rate of its slowest component, 1 request per second. At best, the slowest processing element runs continuously, next slowest processing element is idle 50% of the time waiting for input, and the fastest processing element is idle 75% of the time. On average, the system hardware is idle 40% of the time and not doing useful work. In case two, a parallelized system of four separate parallel pipelines each run at one request per second, giving a total capacity of four requests per second, but at the cost of a 4× increase in the hardware used. Processing elements still average 40% idle, where faster processors wait for slower processing elements to provide input, but has 4× as much hardware idle. This falls far short of the goal of 100% utilization and 0% idle time. In case three, a different implementation, with the same performance as in case two but using five fewer processing elements, combines parallel and serial processing to take advantage of the fact that faster processing elements can handle input from multiple, slower processing elements. By using less hardware in this processing pipeline, it frees hardware resources for use elsewhere in the application-specific processor.

Rate balancing requires two source of input. First, it requires descriptions of the serial pipelines and opportunities for parallelism, specified in the domain-specific policy information. Second, it requires speed estimates. These are generated in the hardware resource mapper, since they depend on the circuit delays in the hardware allocated to the logic design. As with the hardware allocation estimates, precise timing estimates depend on many factors, and precise estimation techniques are not known. Improvements in the hardware resource mapper, noted above, will create improved timing estimates that will benefit this phase of compilation.

In microarray analysis many important techniques are based on examining combinations of thousands of vectors. When the size of the combination is >2, the number of combinations is very large, although the number of actual vectors is quite manageable. In programmable circuits, it is possible to perform hundreds of the computations in parallel making these computations tractable. For this purpose the routing of the vectors from the storage to the parallel computation units is scheduled so that combinations are available for processing at least once, but rarely more than that.

Programmable circuits allow minimization of chip resources as a function of the computation. This allows chip resources to be used for other purposes, e.g. additional parallelism, additional computations, error checking, storage, etc. One minimization is in the number of bits in the data path including ALUs, multipliers etc. from the 32 or 64 bits in a microprocessor down to something smaller, including sometimes a single bit. It is desirable to use a minimum of bits consistent with computational efficacy.

The process includes analysis of the arithmetic the using probability density functions to represent ranges of possible values or to represent uncertainty due to quantization errors providing a superset of worst-case analysis and giving much more statistical information and thus allows for substantially more efficiency.

The parallelism/resource balancing processor 18e provides the information generated therein to a hardware description language (HDL) generator 18f. The HDL generator receives the abstract concepts defined by the user-supplied application logic, the specific numbers of units that the hardware should be able to manage, the specific number of units involved in rate balancing, etc. as provided in units 18b-18e and generates code which is suitable for use by the compiler 22 and code generator 21 described above in conjunction with FIG. 1.

There are two sources of input to this phase of compilation. First, is the set of data structures 18e-f resulting from the parallelism and resource balancing phase. Second is the application-independent HDL code 20c-18f. There are two outputs from this phase. Output 18-21 enables correct interaction between the host and the application-specific accelerator. Output 18-22 consists of HDL code that specifies all of the application-specific acceleration logic. No further processing is done within this compiler on those outputs, but they are processed by compilation and synthesis outside of this system.

Data 18-21 consists of host interface software in some conventional programming language, such as C. This software is a code fragment to be incorporated in an executable application that would manage operation and data handling within the processor acting as host to the FPGA accelerator hardware. This software consists of the interface definitions needed to ensure that the host application and the FPGA content use mutually compatible data formats, access protocols, etc. for exchange of data and control information between the host and the FPGA accelerator. The 18-21 data is unique to each application, and is additional to and dependent on device driver or other host software that communicates with the FPGA accelerator hardware.

Data 18-22 is the full set of HDL code needed for synthesizing an application-specific accelerator.

The HDL output may be provided, for example, in the Verilog HDL. Once all variable factors in the logic design have been determined completely, the HDL generator creates a compliable, synthesizable representation of the entire system design. This consists of two parts, corresponding to the two parts of the target system's hardware configuration.

Each block represents a logical function, and may be replaced with another block serving the same general purpose. For example, it may be possible to select between different implementations of unit 18f, according to the implementer's choice of hardware description language (HDL) such as VHDL, VERILOG, or SYSTEM C as an output representation, and according to the specific needs of each compiler implementation 22 for a given language. As one example, a VHDL compiler from one vendor may require specific signal data types in order to generate a RAM, but another VHDL compiler may require specific settings of named attributes to produce the same result. Any such differences in the tools environment are accommodated using matching versions of the HDL generator 18f.

The invention provides a bioinformatics friendly system for FPGA programming by combining FPGA design expertise in units 20a-20c so that the process of compiling an actual FPGA configuration to solve a bioinformatics problem is accessible to the bioinformatics expert. The invention is not bioinformatics limited and can be applied to any area of technology such as complex image analysis by having preset units 20a-20c programmed or designed by design experts to take cognizance of the input requirements of the problems encountered in that area of technology so an expert in that area alone can achieve high speed analysis in the PC (or other processor) environment.

In use and as shown in FIG. 2, a system providing for rapidly performing computations in a applications such as bioinformatics requiring large amounts of data manipulation includes a processing platform 30 which is typically a PC workstation having a host processor 32 is accelerated with an FPGA co-processor circuit board 34 having disposed thereon an FPGA circuit 36 as programmed for specific application solving according to the compilation functions described above. The preset constraints for the FPGA board are stored in a memory 38.

The FPGA circuit code 44 generated by the system of FIG. 1 is loaded into the FPGA using any technique known to those of ordinary skill in the art to configure the FPGA to perform certain processing functions. The host interface program 40 generated by the system of FIG. 1 is combined with processor 32 specific instructions as a host interface program which is loaded into and executed by the host processor 32. The special purpose FPGA co-processor 34 plugs into the processing platform 30 at an available site to function as an accelerator whose operation, just like with a designer specifiable graphics card, is transparent to a user 42.

The processor hardware is thus supported through a language/function-library infrastructure from the compilation function above to make the plug-in card usable to the application developer as a standard high-level programming language. Usability requires that the end users be given the tools so that they can, with minimal training, use them.

1. An accelerated processor for use in massive data manipulations specific to an application comprising:
a workstation having a general purpose processor and a coprocessor connection;
an application specific coprocessor system at said connection;
said coprocessor system having programming code which is a assembled as instructions for said specific application in combination with accelerator environment specific requirements, independently provided.

2. An application specific coprocessor system for use with a processor for use in massive data manipulations specific to an application and adapted for attachment to a workstation having a general purpose processor, said coprocessor system having programming code which is assembled as instructions for said specific application in combination with accelerator environment specific requirements, independently provided.

3. The coprocessor of claim 2 wherein:
said environment specific instructions are accessed by a compiler in response to user input in an application specific form.

4. The coprocessor of claim 3 wherein said compiler comprises one or more of: user interface to permit an application trained non circuit design trained user to enter instructions to achieve accelerated performance, means to create an internal representation reflecting the operational characteristics of a coprocessor corresponding to application specific accelerated processing needs, means for identifying bit demands for the application specific coprocessor acceleration function, mapper means for identifying resources available and needed for the coprocessor to provide application specific accelerated processing, balancing means for identifying the step by step hardware needs of the coprocessor for the application specific acceleration.

5. The coprocessor of claim 4 wherein said mapper means accepts as input domain-specific policy information, estimates of the amount of logic needed for each processing element, and hardware context information that states what amounts of each logic resource exist on a given coprocessor to enable the largest possible number of processing elements said coprocessor can support.

6. The coprocessor of claim 5 wherein said balancing means analyzes the processing speed of said coprocessor at each step and allocates parallel hardware in proportion to a speed requirement.

7. The coprocessor of claim 3 wherein said compiler further includes one or more of prerecorded information; reflecting the programming requirements for a general area of applications; programming content which reflects application requirements and hardware characteristics; and coprocessor specific hardware availability.

8. A method for programming an accelerating coprocessor comprising the steps of:
accessing data reflective of programming requirements for a general area of applications.

9. The method for programming an accelerating coprocessor of claim 8 comprising the steps of:
accessing data reflective of programming content which reflects application requirements and hardware characteristics.

10. The method for programming an accelerating coprocessor of claim 8 comprising the steps of:
accessing data reflective of coprocessor specific hardware availability.

11. The method of claim 8 further comprising the steps of:
permitting an application trained non circuit design trained user to enter instructions to achieve accelerated performance.

12. The method of claims 8 further comprising the steps of:
creating an internal representation reflecting the operational characteristics of a coprocessor corresponding to application specific accelerated processing needs.

13. The method of claim 8 further comprising the steps of:
identifying bit demands for the application specific coprocessor acceleration function, means for identifying correlating available and needed for the coprocessor to provide application specific accelerated processing.

14. The method of claim 8 further comprising the steps of:
identifying the step by step hardware needs of the coprocessor for the application specific acceleration.

15. A method of compiling data for programming an accelerating coprocessor comprising the steps of:
permitting an application trained non circuit design trained user to enter instructions to achieve accelerated performance

16. A method of compiling data for programming an accelerating coprocessor comprising the steps of:
creating an internal representation reflecting the operational characteristics of a coprocessor corresponding to application specific accelerated processing needs, means for identifying bit demands for the application specific coprocessor acceleration function.

17. A method of compiling data for programming an accelerating coprocessor comprising the steps of:
identifying resources available and needed for the coprocessor to provide application specific accelerated processing.

18. The method of claim 17 wherein said identifying step further includes the step of accepting as input domain-specific policy information, estimates of an amount of logic needed for each processing element, and hardware context information that states what amounts of each logic resource exist in a given coprocessor and providing a design maximizing a number of processing elements that the coprocessor can support.

19. A method of compiling data for programming an accelerating coprocessor comprising the steps of:
identifying the step by step hardware needs of the coprocessor for the application specific acceleration.

20. The method of claim 19 wherein said identifying step includes analyzing the processing speed at each step and allocating parallel hardware in proportion to a processing speed requirement.

21. A compiler for programming an accelerating coprocessor comprising:
means for accessing data reflective of programming requirements for a general area of applications.

22. The compiler for programming an accelerating coprocessor of claim 21 further comprising:
means for accessing data reflective of programming content which reflects application requirements and hardware characteristics.

23. The compiler for programming an accelerating coprocessor of claim 21 further comprising:
means for accessing data reflective of coprocessor specific hardware availability.

24. The compiler of claim 21 further comprising:
means for permitting an application trained non circuit design trained user to enter instructions to achieve accelerated performance.

25. The compiler of claim 21 further comprising:
means for creating an internal representation reflecting the operational characteristics of a coprocessor corresponding to application specific accelerated processing needs.

26. The compiler of claim 21 further comprising:
means for identifying bit demands for the application specific coprocessor acceleration function.

27. The compiler of claim 21 further comprising means for identifying resources available and needed for the coprocessor to provide application specific accelerated processing.

28. The compiler of claim 21 further comprising:
means for identifying the step by step hardware needs of the coprocessor for the application specific acceleration.

29. A compiler for data for programming an accelerating coprocessor comprising:
means for permitting an application trained non circuit design trained user to enter instructions to achieve accelerated performance

30. A compiler for data for programming an accelerating coprocessor comprising:
means for creating an internal representation reflecting the operational characteristics of a coprocessor corresponding to application specific accelerated processing needs, means for identifying bit demands for the application specific coprocessor acceleration function.

31. A compiler for data for programming an accelerating coprocessor comprising:
means for identifying resources available and needed for the coprocessor to provide application specific accelerated processing.

32. The compiler of claim 31 wherein said identifying means further includes means for accepting as input domain-specific policy information, estimates of an amount of logic needed for each processing element, and hardware context information that states what amounts of each logic resource exist in a given coprocessor and providing a design maximizing a number of processing elements that the coprocessor can support.

33. A compiler for data for programming an accelerating coprocessor comprising:
means for identifying the step by step hardware needs of the coprocessor for the application specific acceleration.

34. The compiler of claim 33 wherein said identifying means includes means for analyzing the processing speed at each step and allocating parallel hardware in proportion to a processing speed requirement.

35. The coprocessor of claim 2 wherein:
said environment specific instructions are accessed by a compiler in response to user input in an application specific form.

36. The method of claim 10 further comprising the steps of:
permitting an application trained non circuit design trained user to enter instructions to achieve accelerated performance.

37. The method of claim 36 further comprising the steps of:
creating an internal representation reflecting the operational characteristics of a coprocessor corresponding to application specific accelerated processing needs.

38. The method of claim 37 further comprising the steps of:
identifying bit demands for the application specific coprocessor acceleration function, means for identifying correlating available and needed for the coprocessor to provide application specific accelerated processing.

39. The method of claim 38 further comprising the steps of:
identifying the step by step hardware needs of the coprocessor for the application specific acceleration.

40. The method of claim 11 further comprising the steps of:
creating an internal representation reflecting the operational characteristics of a coprocessor corresponding to application specific accelerated processing needs.

41. The method of claim 40 further comprising the steps of:
identifying bit demands for the application specific coprocessor acceleration function, means for identifying correlating available and needed for the coprocessor to provide application specific accelerated processing.

42. The method of claim 41 further comprising the steps of:
identifying the step by step hardware needs of the coprocessor for the application specific acceleration.

43. The method of claim 12 further comprising the steps of:
identifying bit demands for the application specific coprocessor acceleration function, means for identifying correlating available and needed for the coprocessor to provide application specific accelerated processing.

44. The method of claim 43 further comprising the steps of:
identifying the step by step hardware needs of the coprocessor for the application specific acceleration.

45. The method of claim 13 further comprising the steps of:
identifying the step by step hardware needs of the coprocessor for the application specific acceleration.

46. The compiler of claim 23 further comprising:
means for permitting an application trained non circuit design trained user to enter instructions to achieve accelerated performance.

47. The compiler of claim 46 further comprising:
means for creating an internal representation reflecting the operational characteristics of a coprocessor corresponding to application specific accelerated processing needs.

48. The compiler of claim 47 further comprising:
means for identifying bit demands for the application specific coprocessor acceleration function.

49. The compiler of claim 48 further comprising means for identifying resources available and needed for the coprocessor to provide application specific accelerated processing.

50. The compiler of claim 49 further comprising:
means for identifying the step by step hardware needs of the coprocessor for the application specific acceleration.

51. The compiler of claim 24 further comprising:
means for creating an internal representation reflecting the operational characteristics of a coprocessor corresponding to application specific accelerated processing needs.

52. The compiler of claim 51 further comprising:
means for identifying bit demands for the application specific coprocessor acceleration function.

53. The compiler of claim 52 further comprising means for identifying resources available and needed for the coprocessor to provide application specific accelerated processing.

54. The compiler of claim 53 further comprising:
means for identifying the step by step hardware needs of the coprocessor for the application specific acceleration.

55. The compiler of claim 25 further comprising:
means for identifying bit demands for the application specific coprocessor acceleration function.

56. The compiler of claim 55 further comprising means for identifying resources available and needed for the coprocessor to provide application specific accelerated processing.

57. The compiler of claim 56 further comprising:
means for identifying the step by step hardware needs of the coprocessor for the application specific acceleration.

58. The compiler of claim 26 further comprising means for identifying resources available and needed for the coprocessor to provide application specific accelerated processing.

59. The compiler of claim 58 further comprising:
means for identifying the step by step hardware needs of the coprocessor for the application specific acceleration.

60. The compiler of claim 27 further comprising:
means for identifying the step by step hardware needs of the coprocessor for the application specific acceleration.
